(19) United States
(12) Patent Application Publication
(10) Pub. No.: US 2023/0205073 A1
(43) Pub. Date: Jun. 29, 2023

(54) PELLICLE FOR EUV LITHOGRAPHY MASKS AND METHODS OF MANUFACTURING THEREOF

(71) Applicant: TAIWAN SEMICONDUCTOR MANUFACTURING COMPANY, LTD., Hsinchu (TW)

(72) Inventors: Tzu-Ang CHAO, Hsinchu (TW); Ming-Yang LI, Hsinchu City (TW); Chao-Ching CHENG, Hsinchu City (TW); Han WANG, Hsinchu (TW)

(21) Appl. No.: 17/710,545

(22) Filed: Mar. 31, 2022

Related U.S. Application Data
(60) Provisional application No. 63/294,719, filed on Dec. 29, 2021.

(51) Int. Cl. G03F 1/64

(52) U.S. Cl. CPC G03F 1/64

(57) ABSTRACT

A pellicle for an extreme ultraviolet (EUV) reflective mask includes a pellicle frame and a main membrane attached to the pellicle frame. The main membrane includes a plurality of nanotubes, each of which includes a single nanotube or a co-axial nanotube, and the single nanotube or an outermost nanotube of the co-axial nanotube is a non-carbon based nanotube.

### RELATED APPLICATIONS

This application claims priority of U.S. Provisional Pat. Application No. 63/294,719 filed on Dec. 29, 2021, the entire contents of which are incorporated herein by reference. Further, the entire contents of U.S. Provisional Pat. Application Nos. 63/230,555 and 63/230,576 both filed Aug. 6, 2021 are incorporated herein by reference.

### BACKGROUND

A pellicle is a thin transparent film stretched over a frame that is glued over one side of a photo mask to protect the photo mask from damage, dust and/or moisture. In extreme ultraviolet (EUV) lithography, a pellicle having a high transparency in the EUV wavelength region, a high mechanical strength and a low thermal expansion is generally required.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B show pellicles for an EUV photo mask in accordance with embodiments of the present disclosure.

FIGS. 2A, 2B, 2C and 2D show various views of multiwall nanotubes in accordance with embodiments of the present disclosure.

FIGS. 3A and 3B show various network membranes 100 of a pellicle for an EUV photo mask in accordance with embodiments of the present disclosure

FIGS. 4A, 4B, 4C and 4D show various views of network membranes of a pellicle for an EUV photo mask in accordance with embodiments of the present disclosure.

FIGS. 5A, 5B and 5C show manufacturing of nanotube network membranes for a pellicle in accordance with embodiments of the present disclosure.

FIGS. 6A, 6B, 6C and 6D show manufacturing of nanotube network membranes for a pellicle in accordance with embodiments of the present disclosure.

FIG. 7A shows a manufacturing process of a network membrane, and FIG. 7B shows a flow chart thereof in accordance with an embodiment of the present disclosure.

FIGS. 8A, 8B and 8C show manufacturing processes of multiwall nanotubes in accordance with embodiments of the present disclosure. FIGS. 8D and 8E show structures of multiwall nanotubes in accordance with embodiments of the present disclosure.

FIGS. 9A, 9B and 9C show network membranes formed by multiwall nanotubes with two-dimensional material layers in accordance with some embodiments of the present disclosure.

FIGS. 10A and 10B show a cross sectional view and a plan (top) view of one of the various stages for manufacturing a pellicle for an EUV photo mask in accordance with an embodiment of the present disclosure.

FIGS. 11A and 11B show a cross sectional view and a plan (top) view of one of the various stages for manufacturing a pellicle for an EUV photo mask in accordance with an embodiment of the present disclosure.

FIGS. 12A and 12B show a cross sectional view and a plan (top) view of one of the various stages for manufacturing a pellicle for an EUV photo mask in accordance with an embodiment of the present disclosure.

FIGS. 13A and 13B show a cross sectional view and a plan (top) view of one of the various stages for manufacturing a pellicle for an EUV photo mask in accordance with an embodiment of the present disclosure.

FIG. 14A shows a cross sectional view of one of the various stages for manufacturing a pellicle for an EUV photo mask in accordance with an embodiment of the present disclosure. FIG. 14B shows cross sectional views of the various stages for manufacturing a pellicle for an EUV photo mask in accordance with an embodiment of the present disclosure.

FIGS. 15A, 15B and 15C show flowcharts of manufacturing a pellicle for an EUV photo mask in accordance with embodiments of the present disclosure.

FIGS. 16A, 16B, 16C, 16D and 16E show perspective views of pellicles for an EUV photo mask in accordance with embodiments of the present disclosure.

FIG. 17A shows a flowchart of a method making a semiconductor device, and FIGS. 17B, 17C, 17D and 17E show a sequential manufacturing operation of a method of making a semiconductor device in accordance with embodiments of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B and one from C, unless otherwise explained. Materials, configurations, structures, operations and/or dimensions explained with one embodiment can be applied to other embodiments, and detained description thereof may be omitted.

EUV lithography is one of the crucial techniques for extending Moore’s law. However, due to wavelength scaling from 193 nm (ArF) to 13.5 nm, the EUV light source suffers from strong power decay due to environmental adsorption. Even though a stepper/scanner chamber is operated under vacuum to prevent strong EUV adsorption by gas, maintaining a high EUV transmittance from the EUV light source to a wafer is still an important factor in EUV lithography.

A pellicle generally requires a high transparency and a low reflectivity. In UV or DUV lithography, the pellicle film is made of a transparent resin film. In EUV lithography, however, a resin based film would not be acceptable, and a non-organic material, such as a polysilicon, silicide or metal film, is used.

Carbon nanotubes (CNTs) are one of the materials suitable for a pellicle for an EUV reflective photo mask, because CNTs have a high EUV transmittance of more than 96.5%. Generally, a pellicle for an EUV reflective mask requires the following properties: (1) Long life time in a hydrogen radical rich operation environment in an EUV stepper/scanner; (2) Strong mechanical strength to minimize the sagging effect during vacuum pumping and venting operations; (3) A high or perfect blocking property for particles larger than about 20 nm (killer particles); and (4) A good heat dissipation to prevent the pellicle from being burnt out by EUV radiation. Other nanotubes made of a non-carbon based material are also usable for a pellicle for an EUV photo mask. In some embodiments of the present disclosure, a nanotube is a one dimensional elongated tube having a dimeter in a range from about 0.5 nm to about 100 nm.

In the present disclosure, a pellicle for an EUV photo mask includes a network membrane having a plurality of multiwall nanotubes that form a mesh structure having voids and a two-dimensional material layer at least partially filling the voids. Such a pellicle has a high EUV transmittance, improved mechanical strength, blocks killer particles from falling on an EUV mask, and/or has improved durability.

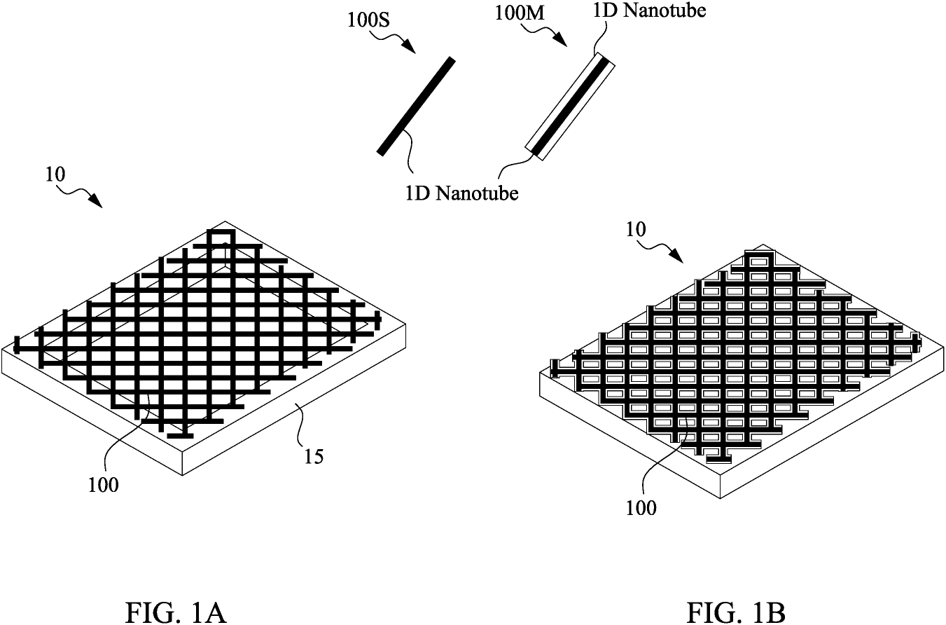

FIGS. 1A and 1B show EUV pellicles 10 in accordance with an embodiment of the present disclosure. In some embodiments, a pellicle 10 for an EUV reflective mask includes a main network membrane 100 disposed over and attached to a pellicle frame 15. In some embodiments, as shown in FIG. 1A, the main network membrane 100 includes a plurality of single wall nanotubes 100S, and in other embodiments, as shown in FIG. 1B, the main network membrane 100 includes a plurality of multiwall nanotubes 100D. In some embodiments, the single wall nanotubes are carbon nanotubes, and in other embodiments, the single wall nanotubes are nanotubes made of a non-carbon based material. In some embodiments, the non-carbon based material includes at least one of boron nitride (BN) or transition metal dichalcogenides (TMDs), represented by MX₂, where M=Mo, W, Pd, Pt, and/or Hf, and X=S, Se and/or Te. In some embodiments, a TMD is one of MoS₂, MoSe₂, WS₂ or WSe₂.

In some embodiments, a multiwall nanotube is a co-axial nanotube having two or more tubes co-axially surrounding an inner tube(s). In some embodiments, the main network membrane 100 includes only one type of nanotubes (single wall/multiwall, or material) and in other embodiments, different types of nanotubes form the main network membrane 100.

In some embodiments, a pellicle (support) frame 15 is attached to the main network membrane 100 to maintain a space between the main network membrane of the pellicle and an EUV mask (pattern area) when mounted on the EUV mask. The pellicle frame 15 of the pellicle is attached to the surface of the EUV photo mask with an appropriate bonding material. In some embodiments, the bonding material is an adhesive, such as an acrylic or silicon based glue or an A-B cross link type glue. The size of the frame structure is larger than the area of the black borders of the EUV photo mask so that the pellicle covers not only the circuit pattern area of the photo mask but also the black borders.

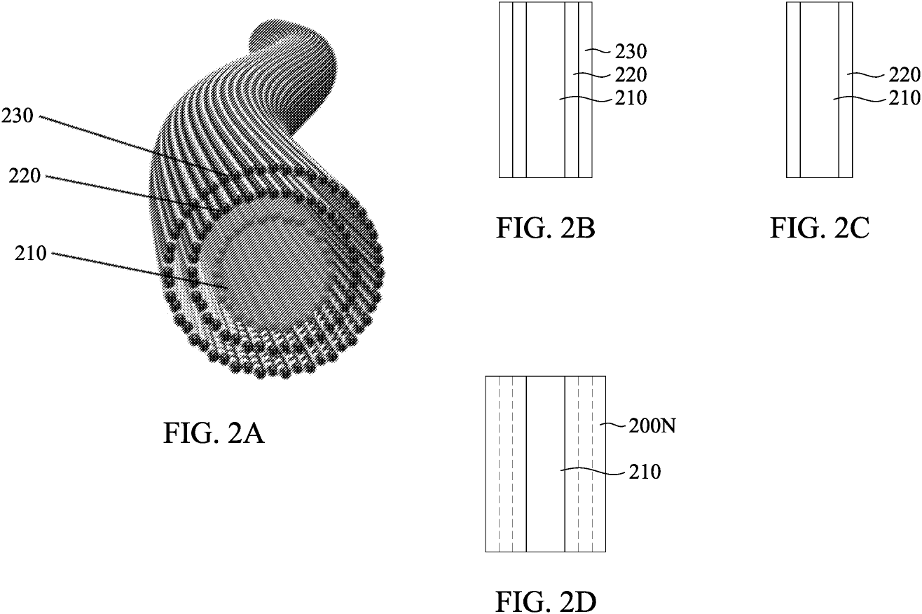

FIGS. 2A, 2B, 2C and 2D show various views of multiwall nanotubes in accordance with embodiments of the present disclosure.

In some embodiments, the nanotubes in the main network membrane 100 include multiwall nanotubes, which are also referred to as co-axial nanotubes. FIG. 2A shows a perspective view of a multiwall co-axial nanotube having threes tubes 210, 220 and 230 and FIG. 2B shows a cross sectional view thereof. In some embodiments, the inner tube 210 is a carbon nanotube, and two outer tubes 220 and 230 are non-carbon based nanotubes, such as boron nitride nanotubes. In some embodiments, the all tubes are non-carbon based nanotubes.

The number of tubes of the multiwall nanotubes is not limited to three. In some embodiments, the multiwall nanotube has two co-axial nanotubes as shown in FIG. 2C, and in other embodiments, the multiwall nanotube includes the innermost tube 210 and the first to N-th nanotubes including the outermost tube 200N, where N is a natural number from 1 to about 20, as shown in FIG. 2D. In some embodiments, N is up to 10 or up to 5. In some embodiments, at least one of the first to the N-th outer layers is a nanotube coaxially surrounding the innermost nanotube 210. In some embodiments, two of the innermost nanotubes 210 and the first to the N-th outer layers 220, 230, ... 200N are made of different materials from each other. In some embodiments, N is at least two (i.e., three or more tubes), and two of the innermost nanotubes 210 and the first to the N-th outer tubes 220, 230, ... 200N are made of the same materials. In other embodiments, three of the innermost nanotubes 210 and the first to the N-th outer tubes 220, 230, ... 200N are made of different materials from each other.

In some embodiments, each of the nanotubes of the multiwall nanotube is one selected from the group consisting of a carbon nanotube, a boron nitride nanotube, a transition metal dichalcogenide (TMD) nanotube, where TMD is represented by MX₂, where M is one or more of Mo, W, Pd, Pt, or Hf, and X is one or more of S, Se or Te. In some embodiments, at least two of the tubes of the multiwall nanotube are made of a different material from each other. In some embodiments, adjacent two layers (tubes) of the multiwall nanotube are made of a different material from each other. In some embodiments, an outermost nanotube of the multiwall nanotube is a non-carbon based nanotube.

In some embodiments, the outermost tube or outermost layer of the multiwall nanotubes is made of at least one layer of an oxide, such as HfO₂, Al₂O₃, ZrO₂, Y₂O₃, or La₂O₃; at least one layer of non-oxide compounds, such as B₄C, YN, Si₃N₄, BN, NbN, RuNb, YF₃, TiN, or ZrN; or at least one metal layer made of, for example, Ru, Nb, Y, Sc, Ni, Mo, W, Pt, or Bi.

In some embodiments, the multiwall nanotube includes three co-axially layered tubes made of different materials from each other. In other embodiments, the multiwall nanotube includes three co-axially layered tubes, in which the innermost tube (first tube) and the second tube surrounding the innermost tube are made of materials different from each other, and the third tube surrounding the second tube is made of the same material as or different material from the innermost tube or the second tube.

In some embodiments, the multiwall nanotube includes four co-axially layered tubes each made of different materials A, B or C. In some embodiments, the materials of the four layers are from the innermost (first) tube to the fourth tube, A/B/A/A, A/B/A/B, A/B/A/C, A/B/B/A, A/B/B/B, A/B/B/C, A/B/C/A, A/B/C/B, or A/B/C/C.

In some embodiments, all the tubes of the multiwall nanotube are crystalline nanotubes. In other embodiments, one or more tubes are a non-crystalline (e.g., amorphous) layer wrapping around the one or more inner tubes. In some embodiments, the outermost tube is made of, for example, a layer of HfO₂, Al₂O₃, ZrO₂, Y₂O₃, La₂O₃, B₄C, YN, Si₃N₄, BN, NbN, RuNb, YF₃, TiN, ZrN. Ru, Nb, Y, Sc, Ni, Mo, W, Pt, or Bi.

In some embodiments, a diameter of the innermost nanotube is in a range from about 0.5 nm to about 20 nm and is in a range from about 1 nm to about 10 nm in other embodiments. In some embodiments, a diameter of the multiwall nanotubes (i.e., diameter of the outermost tube) is in a range from about 3 nm to about 40 nm and is in a range from about 5 nm to about 20 nm in other embodiments. In some embodiments, a length of the multiwall nanotube is in a range from about 0.5 µm to about 50 µm and is in a range from about 1.0 µm to about 20 µm in other embodiments.

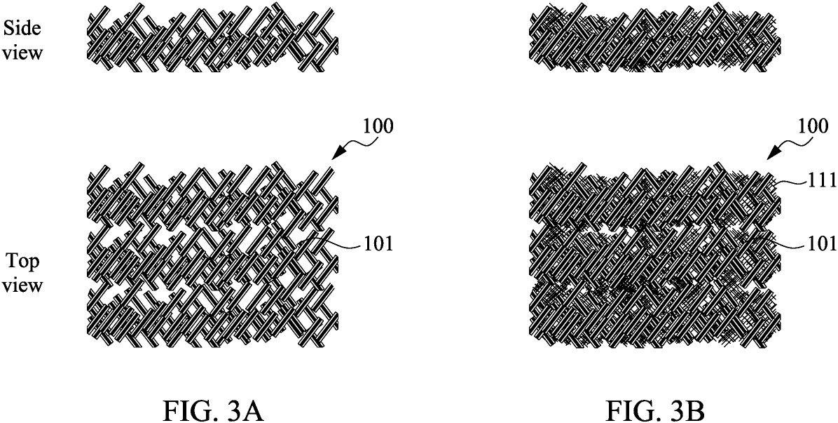

FIGS. 3A and 3B show various network membranes 100 of a pellicle for an EUV photo mask in accordance with embodiments of the present disclosure.

In some embodiments, the network membrane 100 includes a plurality of multiwall nanotubes 101 as shown in FIG. 3A. In some embodiments, the plurality of multiwall nanotubes are randomly arranged to form a network structure, such as a mesh. In some embodiments, the plurality of multiwall nanotubes include only one type of multiwall nanotubes in terms of material and structure (number of layers). In other embodiments, the plurality of multiwall nanotubes include two or more types of multiwall nanotubes in terms of material and structure (number of layers). For example, the plurality of multiwall nanotubes include a first type of multiwall nanotubes, e.g., two wall nanotubes, and a second type of multiwall nanotubes, e.g., three wall nanotubes; a first type of multiwall nanotubes, e.g., two wall nanotubes of layer A and layer B, and a second type of multiwall nanotubes, e.g., two wall nanotubes of layer A and layer C. In some embodiments, different nanotube layers are stacked to form the main network membrane 100.

In some embodiments, the main network layer 100 includes a plurality of one or more types of multiwall nanotubes 101, and a plurality of one or more types of single wall nanotubes 111, as shown in FIG. 3B. In some embodiments, different nanotube layers are stacked to form the main network membrane 100. In some embodiments, an amount (weight) of the single wall nanotubes 111 is smaller than an amount of the multiwall nanotubes 101. In some embodiments, an amount (weight) of the single wall nanotubes 111 is greater than an amount of the multiwall nanotubes 101. In some embodiments, the amount (weight) of the multiwall nanotubes 101 is at least about 20 wt% with respect to a total weight of the network membrane 100, or is at least 40 wt% in other embodiments. When the amount of the multiwall nanotubes is smaller than these ranges, sufficient strength of the network membrane may not be obtained.

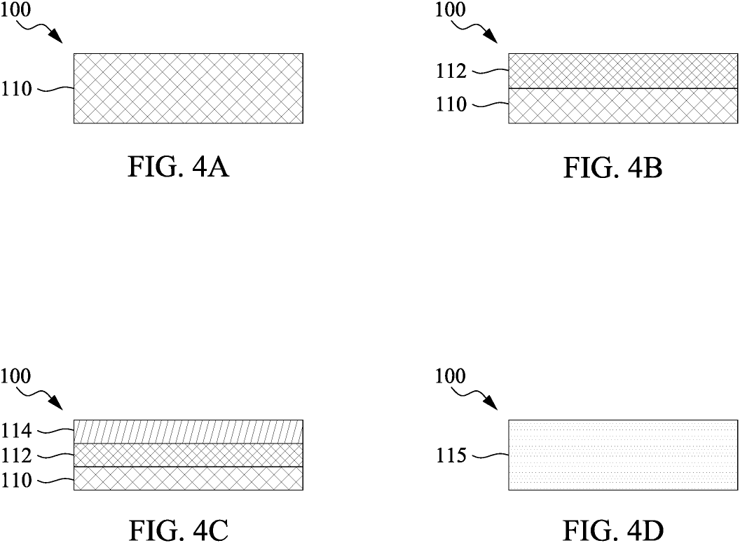

FIGS. 4A, 4B, 4C and 4D show various views of network membranes of a pellicle for an EUV photo mask in accordance with embodiments of the present disclosure. In some embodiments, the network membrane 100 has a single layer structure or a multilayer structure.

In some embodiments, the network membrane 100 has a single layer 110 of a plurality of multiwall nanotubes as shown in FIG. 4A. In some embodiments, the network membrane 100 has two layers of different type multiwall nanotubes 110 and 112, as shown in FIG. 4B. The thickness of the layer 110 and layer 112 are the same or different from each other. In some embodiments, the network membrane 100 has three layers of nanotubes 110, 112 and 114, as shown in FIG. 4C. At least adjacent layers are different types (e.g., material and/or wall numbers) in some embodiments. The thickness of the layers 110, 112 and 114 are the same or different from each other. In some embodiments, a single nanotube layer is disposed between two multiwall nanotube layers. In some embodiments, the network membrane 100 has a single layer 115 of a mixture of different type nanotubes, as shown in FIG. 4D.

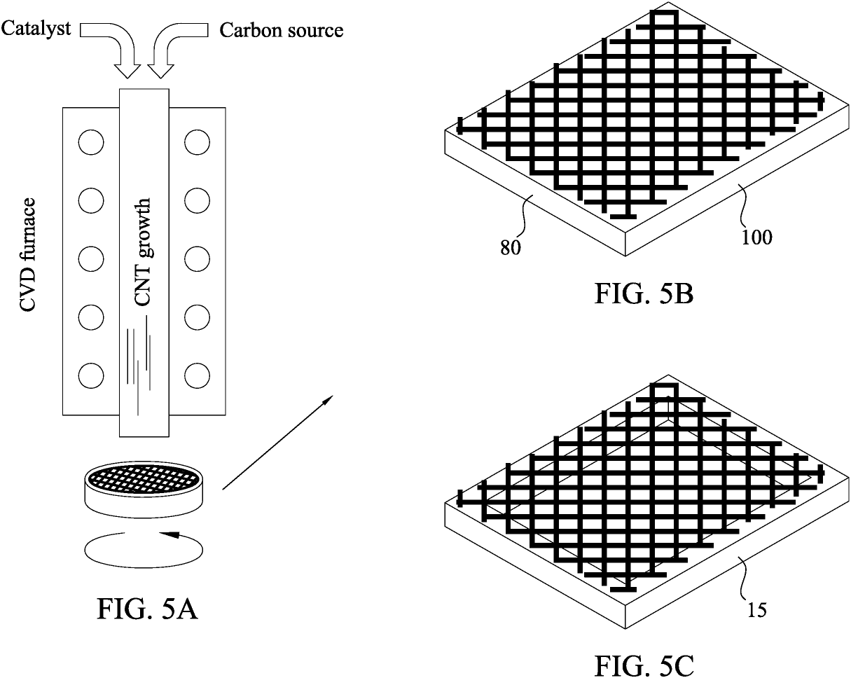

FIGS. 5A, 5B and 5C show the manufacturing of nanotube network membranes for a pellicle in accordance with embodiments of the present disclosure.

In some embodiments, nanotubes are formed by a chemical vapor deposition (CVD) process. In some embodiments, a CVD process is performed by using a vertical furnace as shown in FIG. 5A, and synthesized nanotubes are deposited on a support membrane 80 as shown in FIG. 5B. In some embodiments, carbon nanotubes are formed from a carbon source gas (precursor) using an appropriate catalyst. In other embodiments, non-carbon based nanotubes are formed from appropriate source gases containing B, S, Se, Mo and/or W. Then, the network membrane 100 formed over the support membrane 80 is detached from the support membrane 80, and transferred on to the pellicle frame 15 as shown in FIG. 5C.

In some embodiments, a stage or a susceptor, on which the support membrane 80 is disposed, rotates continuously or intermittently (step-by-step manner) so that the synthesized nanotubes are deposited on the support membrane 80 with different or random directions.

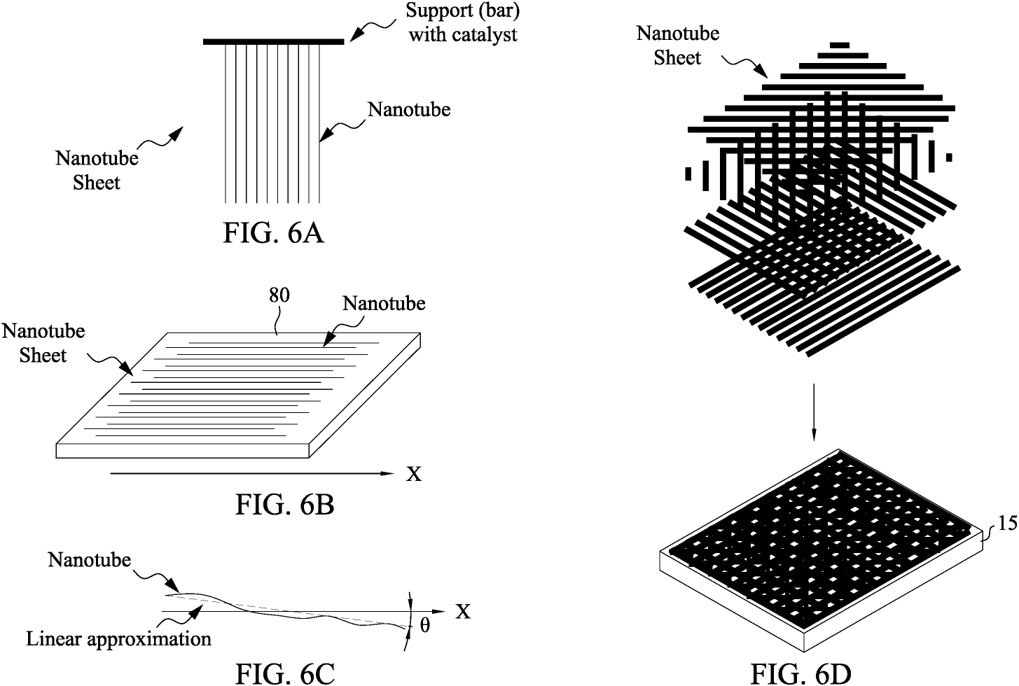

FIGS. 6A, 6B, 6C and 6D show the manufacturing of nanotube network membranes for a pellicle in accordance with embodiments of the present disclosure. In some embodiments, a plurality of elongated nanotubes are formed in a vertical furnace from catalysts attached to a support frame or a support bar as shown in FIG. 6A. In some embodiments, the vertically formed nanotubes form a freestanding sheet of nanotubes. In some embodiments, the nanotubes are entangled with each other in the sheet. In some embodiments, the length of the nanotube sheet is in a range from about 5 cm to about 50 cm.

In some embodiments, after the elongated single wall nanotubes is grown from the catalysts on the support frame or bar, one or more outer nanotubes are formed co-axially wrapping around the single wall nanotubes. In some embodiments, BN nanotubes and/or TMD nanotubes are formed around single wall carbon nanotubes by CVD. In some embodiments, metal sources (Mo, W, etc) and chalcogen source are supplied as gas sources into the vertical furnace. In a case of forming a MoS₂ layer, a Mo(CO)₆ gas, a MoCl₅ gas, and/or a MoOCl₄ gas are used as a Mo source, and a H₂S gas and/or a dimethylsulfide gas are used as a S source, in some embodiments.

In some embodiments, the nanotube sheet is placed on a support membrane 80 as shown in FIG. 6B. In some embodiments, and the support frame or bar is removed (e.g., cut out) and the nanotube sheet is cut into a desired size to fit a reticle frame. In some embodiments, the nanotubes of the nanotube sheet are substantially aligned with a specific direction, e.g., X direction as shown in FIG. 6B. In some embodiments, more than about 90 % of the nanotubes of the nanotube sheet have angles θ of ± 15 degrees with respect to the X direction, when each of the nanotubes of the first layer is subjected to linear approximation as shown in FIG. 6C. In some embodiments, the X direction coincides with the average direction of the linear approximated nanotubes.

In some embodiments, two or more nanotube sheets having a desired shape to fit a pellicle frame are stacked and attached to the pellicle frame 15 forming the network membrane, such that the two adjacent layers of the nanotube sheets have different alignment axes (e.g., different orientations), as shown in FIG. 6D. In some embodiments, the alignment axis of one layer and the alignment axis of the adjacent layer form an angle of about 30 degrees to about 90 degrees. In some embodiments, the number N of layers of the nanotube sheets and the angle difference A between adjacent sheets satisfy N×A=n×180 degrees, where N is a natural number of two or more and n is a natural number of one or more. In some embodiments, N is up to 10. In some embodiments, after the stack of the nanotube sheets are formed, the stacked sheet is cut into a desired shape to form a network membrane and then the network membrane is attached to the pellicle frame.

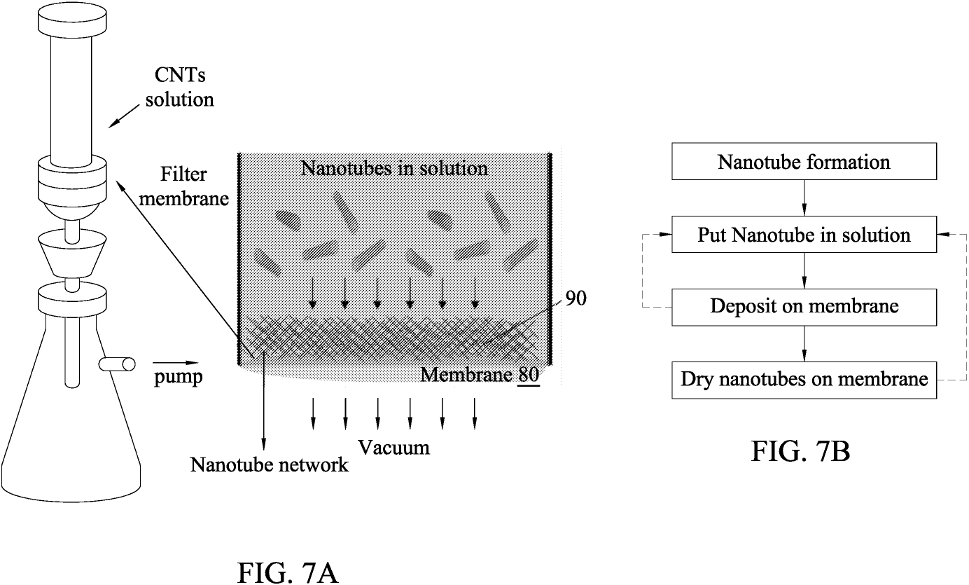

FIG. 7A shows a manufacturing process of a network membrane and FIG. 7B shows a flow chart thereof in accordance with an embodiment of the present disclosure.

In some embodiments, nanotubes are dispersed in a solution as shown in FIG. 7A. The solution includes a solvent, such as water or an organic solvent, and a surfactant, such as sodium dodecyl sulfate (SDS). The nanotubes are one type or two or more types of nanotubes (material and/or wall numbers). In some embodiments, the nanotubes are single wall nanotubes. In some embodiments, single wall nanotubes are carbon nanotubes formed by various methods, such as arc-discharge, laser ablation or chemical vapor deposition (CVD) methods. Similarly, single wall BN nanotubes and single wall TMD nanotubes are also formed by a CVD process.

As shown in FIG. 7A, a support membrane is placed between a chamber or a cylinder in which the nanotube dispersed solution is disposed and a vacuum chamber. In some embodiments, the support membrane is an organic or inorganic porous or mesh material. In some embodiments, the support membrane is a woven or non-woven fabric. In some embodiments, the support membrane has a circular shape in which a pellicle size of a 150 mm × 150 mm square (the size of an EUV mask) can be placed.

As shown in FIG. 7A, the pressure in the vacuum chamber is reduced so that a pressure is applied to the solvent in the chamber or cylinder. Since the mesh or pore size of the support membrane is sufficiently smaller than the size of the nanotubes, the nanotubes are captured by the support membrane while the solvent passes through the support membrane. The support membrane on which the nanotubes are deposited is detached from the filtration apparatus of FIG. 7A and then is dried. In some embodiments, the deposition by filtration is repeated so as to obtain a desired thickness of the nanotube network layer as shown in FIG. 7B. In some embodiments, after the deposition of the nanotubes in the solution, other nanotubes are dispersed in the same or new solution and the filter-deposition is repeated. In other embodiments, after the nanotubes are dried, another filter-deposition is performed. In the repetition, the same type of nanotubes is used in some embodiments, and different types of nanotubes are used in other embodiments. In some embodiments, the nanotubes dispersed in the solution include multiwall nanotubes.

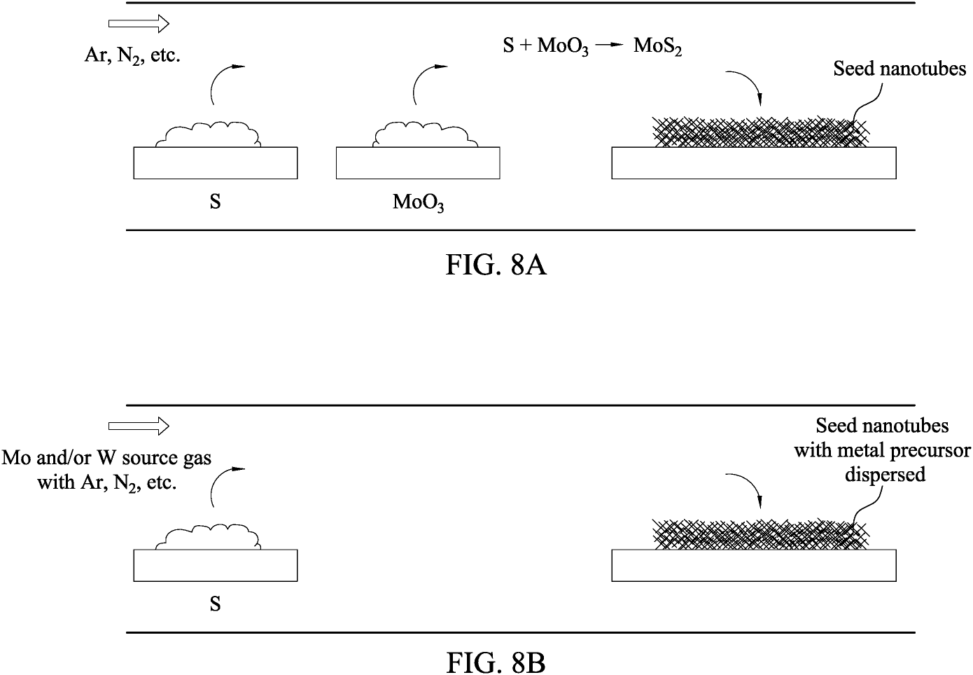

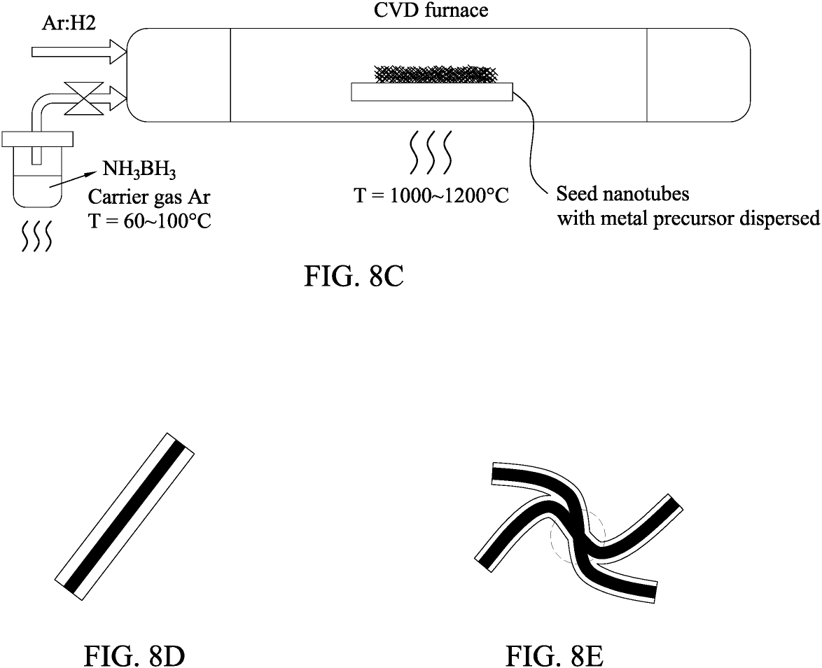

FIGS. 8A, 8B and 8C show manufacturing processes of multiwall nanotubes in accordance with embodiments of the present disclosure. In some embodiments, multiwall nanotubes are formed by CVD by using single wall nanotubes as seeds, as shown in FIG. 8A. In some embodiments, single wall nanotubes, such as carbon nanotubes, BN nanotubes or TMD nanotubes formed by CVD are placed over a substrate. Then, source materials, such as source gases, are provided over the substrate with the seed nanotubes.

In some embodiments, a Mo containing gas (e.g., MoO₃ gas) sublimed from a solid MoO₃ or a MoCl₅ source and/or a S containing gas sublimed from a solid S source is used, as shown in FIG. 8A. As shown in FIG. 8A, solid sources of Mo and S are placed in a reaction chamber and a carrier gas containing an inert gas, such as Ar, N₂ and/or He flows in the reaction chamber. The solid sources are heated to generate gaseous sources by sublimation, and the generated gases react to form MoS₂ molecules. The MoS₂ molecules are then deposited around the seed nanotubes over the substrate. The substrate is appropriately heated in some embodiments. In other embodiments, the entire reaction chamber is heated by induction heating.

In other embodiments, one of the solid sources, e.g., metal sources (Mo, W, etc) is supplied as a gas source into the chamber as shown in FIG. 8B. In a case of forming a MoS₂ layer, Mo(CO)₆ gas, MoCls gas, and/or MoOCl₄ gas are used as a Mo source. When the S source is supplied as a gas, H₂S gas and/or dimethylsulfide gas are used as a S source, in some embodiments. In some embodiments, both the metal source and the chalcogen source are provides as gases.

In some embodiments, multiwall nanotubes having a BN nanotube as an outer nanotube is formed by CVD, as shown in FIG. 8C. In some embodiments, a B source is NH₃BH₃ heated at a temperature in a range from about 60° C. to 100° C. and carried by a carrier gas (e.g., Ar gas). An additional carrier or dilute gas is also used in some embodiments.

Other TMD layers can also be formed by CVD using suitable source gases. For example, metal oxides, such as WO₃, PdO₂ and PtO₂ can be used as a sublimation source for W, Pd and Pt, respectively, and metal compounds, such as W(CO)₆, WF₆, WOCl₄, PtCl₂ andPdCl₂ can also be used as a metal source. In other embodiments, the seed nanotubes are immersed in, dispersed in or treated by, one or more metal precursor, such as (NH₄)WS₄, WO₃, (NH₄)MoS₄ or MoO₃ and placed over the substrate, and then a sulfur gas is provided over the substrate to form multiwall nanotubes.

Three or more co-axial nanotubes are formed by repeating the above processes in some embodiments.

In some embodiments, as shown in FIG. 8D, a multiwall nanotube includes an inner nanotube and an outer nanotube fully coaxially surrounding the inner nanotube. In other embodiments, when the nanotubes used as the seed layer form a network, the outer nanotube coaxially surrounds the inner tube while two or more inner tubes touch each other as shown in FIG. 8E.

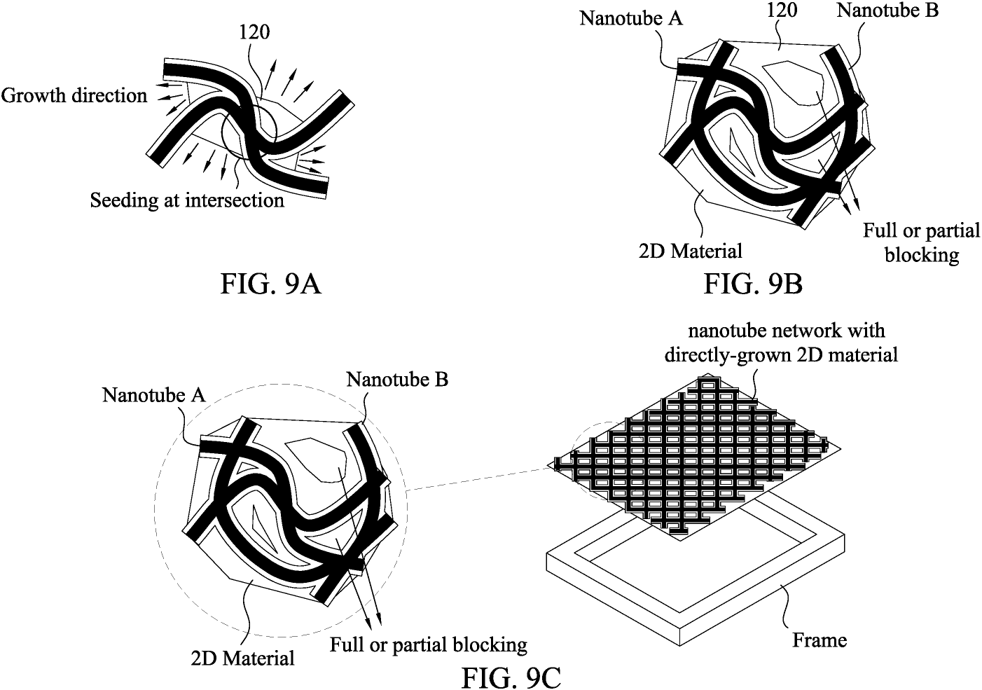

FIGS. 9A, 9B and 9C show network membranes formed by multiwall nanotubes with two dimensional material layers in accordance with some embodiments of the present disclosure.

As set forth above, a network membrane including one or more layers of single wall nanotubes and/or multiwall nanotubes are formed. In some embodiments, each of the layers forms a mesh structure having a plurality of voids or spaces. As shown in FIGS. 9A and 9B, a two-dimensional material layer 120 is formed to partially or fully fill the voids.

In some embodiments, the two-dimensional material layer 120 include at least one of boron nitride (BN), and/or transition metal dichalcogenides (TMDs), represented by MX₂, where M=Mo, W, Pd, Pt, and/or Hf, and X=S, Se and/or Te. In some embodiments, a TMD is one of MoS₂, MoSe₂, WS₂ or WSe₂. In some embodiments, a thickness of the two-dimensional material layer 120 is in a range from about 0.3 nm to about 3 nm and is in a range from about 0.5 nm to about 1.5 nm in other embodiments. In some embodiments, a number of the two-dimensional material layers is 1 to about 20, and is 2 to about 5 in other embodiments.

In some embodiments, the two-dimensional layers are formed by CVD using a transition metal source gas and a chalcogen source gas similar to the processes as explained with respect to FIGS. 8A-8C. In some embodiments, the two-dimensional layer includes graphene formed by CVD using a carbon containing gas. As shown in FIG. 9A, the growth of the two-dimensional material layer starts at and grows out from the intersection, as the seeding sites, of the nanotube network. In some embodiments, the growth of the two-dimensional material layer is combined with the growth of the outer tubes, sequentially or individually. In some embodiments, the BN or TMD outer tubes are formed around the single wall (or multiwall) nanotubes and the two-dimensional layers are continuously formed to fill the voids.

In some embodiments, the network membrane includes the voids each having an area of 10 nm² to 1000 nm² and the two-dimensional layer fills each void by about 30% to about 100% in area in plan view (as a surface area). Thus, some of the voids are fully filled or blocked by the two-dimensional layer, and some of the voids are only partially filled or blocked by the two-dimensional layer.

The network membrane with the two-dimensional material layers is attached to the pellicle frame as shown in FIG. 9C. The two-dimensional layers filling the void provide an excellent heat dissipation path to release heat.

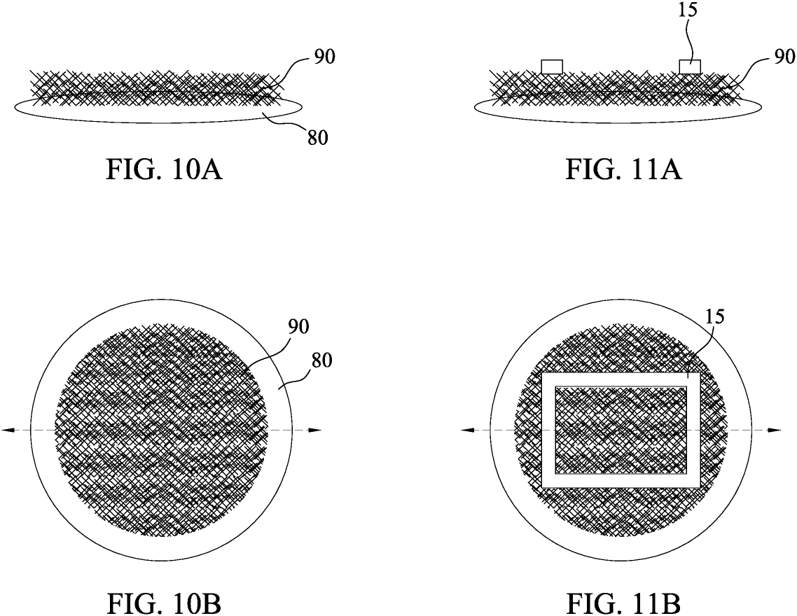

FIGS. 10A and 10B to 13A and 13B show cross sectional views (the “A” figures) and plan (top) views (the “B” figures) of the various stages for manufacturing a pellicle for an EUV photo mask in accordance with an embodiment of the present disclosure. It is understood that additional operations can be provided before, during, and after the processes shown by FIGS. 10A-13B, and some of the operations described below can be replaced or eliminated, for additional embodiments of the method. The order of the operations/processes may be interchangeable. Materials, configurations, methods, processes and/or dimensions as explained with respect to the foregoing embodiments are applicable to the following embodiments, and the detailed description thereof may be omitted.

A nanotube layer 90 is formed on a support membrane 80 by one or more method as explained above. In some embodiments, the nanotube layer 90 includes single wall nanotubes, multi wall nanotubes, or mixture thereof. In some embodiments, the nanotube layer 90 includes single wall nanotubes only. In some embodiments, the single wall nanotubes are non-carbon based nanotubes, such as BN nanotubes or TMD nanotubes.

Then, as shown in FIGS. 11A and 11B, a pellicle frame 15 is attached to the nanotube layer 90. In some embodiments, the pellicle frame 15 is formed of one or more layers of crystalline silicon, polysilicon, silicon oxide, silicon nitride, ceramic, metal or organic material. In some embodiments, as shown in FIG. 11B, the pellicle frame 15 has a rectangular (including square) frame shape, which is larger than the black border area of an EUV mask and smaller than the substrate of the EUV mask.

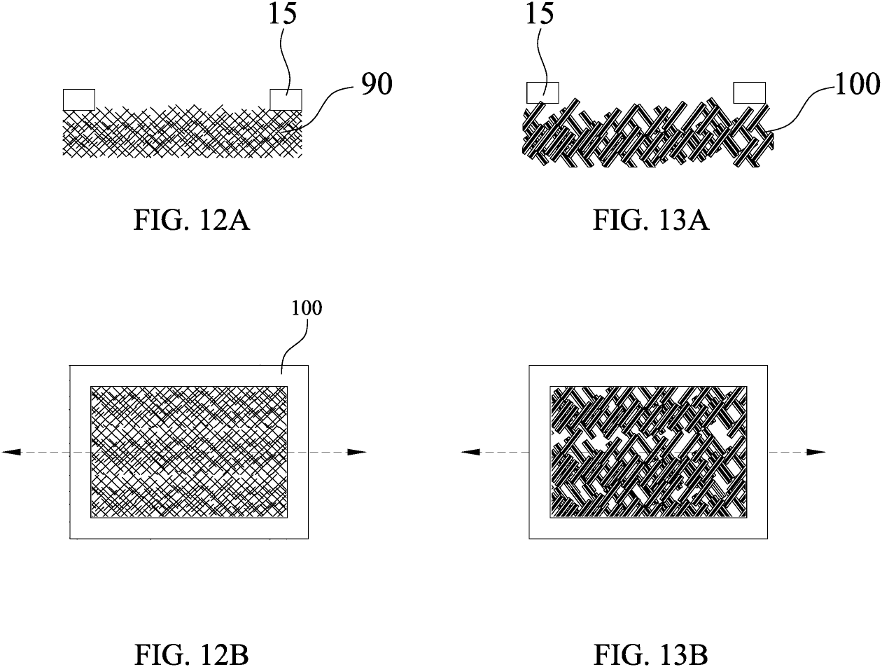

Next, as shown in FIGS. 12A and 12B, the nanotube layer 90 and the support membrane 80 are cut into a rectangular shape having the same size as or slightly larger than the pellicle frame 15, and then the support membrane 80 is detached or removed, in some embodiments. When the support membrane 80 is made of an organic material, the support membrane 80 is removed by wet etching using an organic solvent.

Then, in some embodiments, one or more outer nanotubes are formed around each of the nanotubes (e.g., single nanotubes) and/or two-dimensional material layers are formed to at least partially fill voids of the nanotube layer 90, to form a network membrane 100, as shown in FIGS. 13A and 13B. In some embodiments, a CVD process, as explained above, is performed to form the outer nanotubes and/or the two-dimensional material layers using the nanotube layer 90 as seed layer. The CVD process is repeated a desired number of times to form two or more outer tubes and/or two or more layers of two-dimensional material.

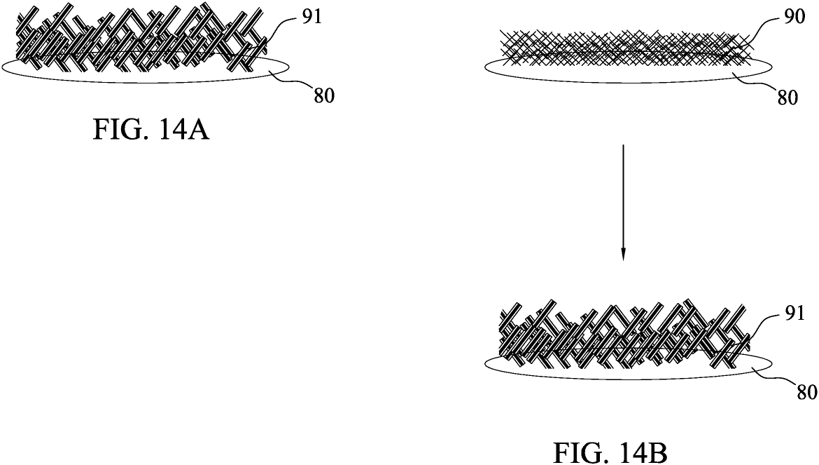

In some embodiments, when a multiwall nanotube layer 91 is directly formed over the support membrane 80, as shown in FIG. 14A. In some embodiments, as shown in FIG. 14B, after the nanotube layer 90 including single wall nanotubes is formed over the support membrane 80, the single nanotubes are converted to multiwall nanotubes over the support substrate 80 and/or the two-dimensional material layers are formed to at least partially fill the void. After the nanotube layer 91 including multiwall nanotubes and/or the two-dimensional material layers is formed over the support membrane, the pellicle frame 15 is attached, and then the nanotube layer is cut into a desired shape.

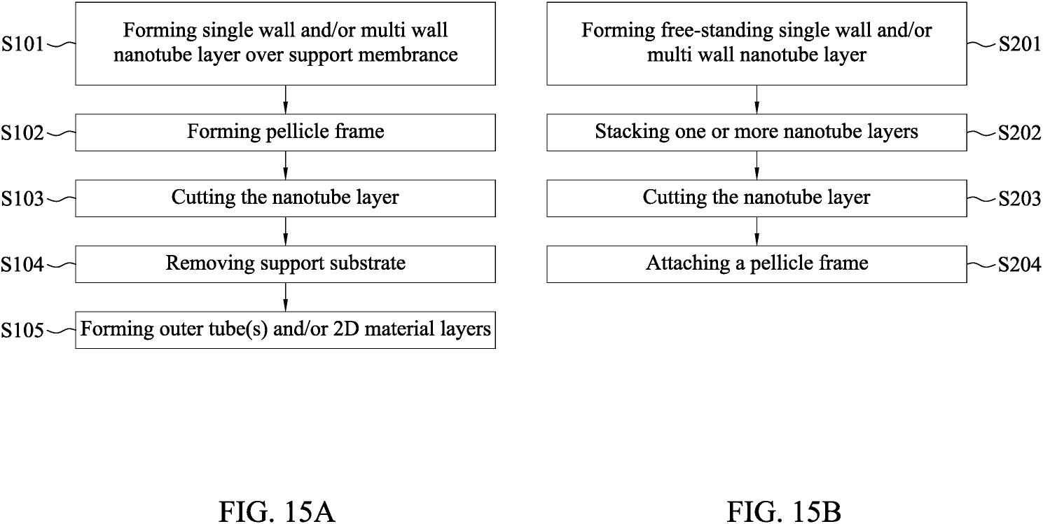

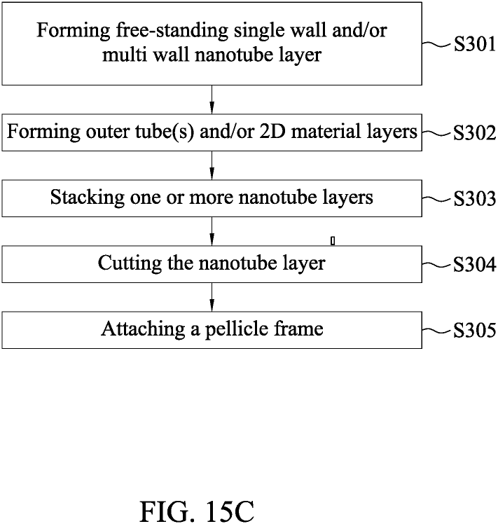

FIGS. 15A, 15B and 15C show flowcharts of manufacturing a pellicle for an EUV photo mask in accordance with embodiments of the present disclosure. It is understood that additional operations can be provided before, during, and after the process blocks shown by FIGS. 15A-15C, and some of the operations described below can be replaced or eliminated for additional embodiments of the method. The order of the operations/processes may be interchangeable. Materials, configurations, methods, processes and/or dimensions as explained with respect to the foregoing embodiments are applicable to the following embodiments, and the detailed description thereof may be omitted.

In some embodiments, as shown in FIG. 15A, a nanotube layer including single wall nanotubes and/or multi wall nanotubes is formed over a support membrane at block S101. Then, at block S102, a pellicle frame is attached to or formed over the nanotube layer. At block S103, the nanotube layer and the support membrane are cut into a desired shape, and at block S104, the support membrane is removed. At block S105, one or more outer tubes are formed around the single wall nanotubes, respectively and/or two-dimensional material layers are formed in the voids of the nanotube layer. In some embodiments, block S015 is performed between blocks S101 and S102. In some embodiments, the single wall nanotubes and/or one of the outer nanotube of the multi wall nanotubes are non-carbon based nanotubes. In other embodiments, the single wall nanotubes and/or an innermost nanotube of the multi wall nanotubes are carbon nanotubes.

In some embodiments, as shown in FIG. 15B, a nanotube layer including single wall nanotubes and/or multi wall nanotubes is formed over a support membrane at block S201. Then, at block S202, two or more nanotube layers formed at block S201 are stacked. In some embodiments, orientations of adjacent two nanotube layers are different from each other. At block S203, the stacked nanotube layers are cut into a desired shape, and at block S204, a pellicle frame is formed over the stacked nanotube layers. In some embodiments, the single wall nanotubes and/or one of the outer nanotube of the multi wall nanotubes are non-carbon based nanotubes. In other embodiments, the single wall nanotubes and/or an innermost nanotube of the multi wall nanotubes are carbon nanotubes.

In some embodiments, as shown in FIG. 15C, a nanotube layer including single wall nanotubes and/or multi wall nanotubes is formed over a support membrane at block S301. Then, at block S302, one or more outer tubes and/or two-dimensional material layers are formed over the nanotubes. At block S303, two or more nanotube layers formed at S302 are stacked. In some embodiments, orientations of adjacent two nanotube layers are different from each other. At block S304, the stacked nanotube layers are cut into a desired shape, and at block S305, a pellicle frame is formed over the stacked nanotube layers. In some embodiments, the single wall nanotubes and/or one of the outer nanotube of the multi wall nanotubes are non-carbon based nanotubes. In other embodiments, the single wall nanotubes and/or an innermost nanotube of the multi wall nanotubes are carbon nanotubes.

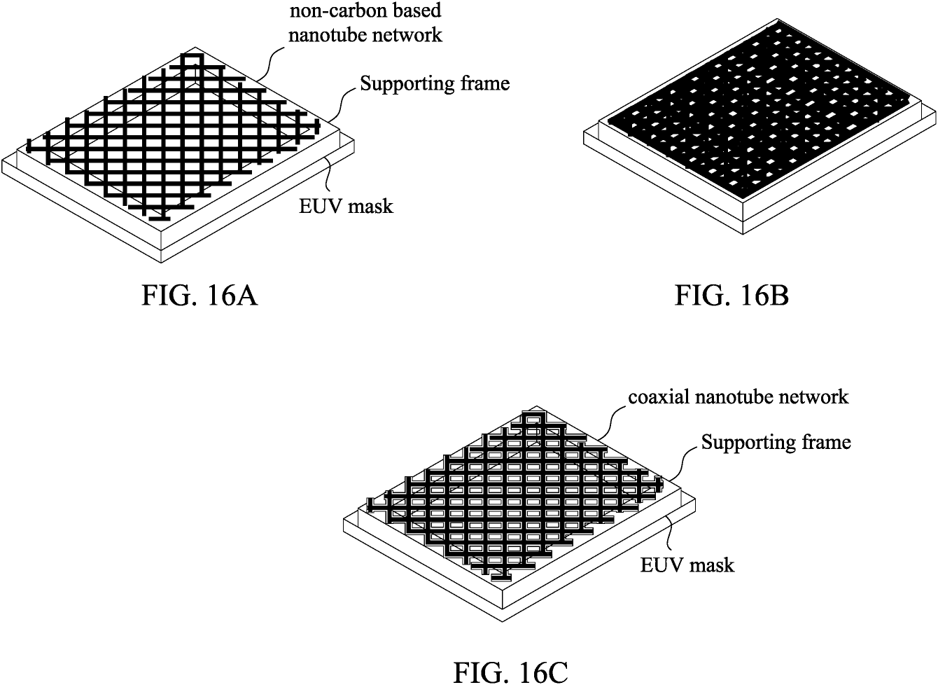

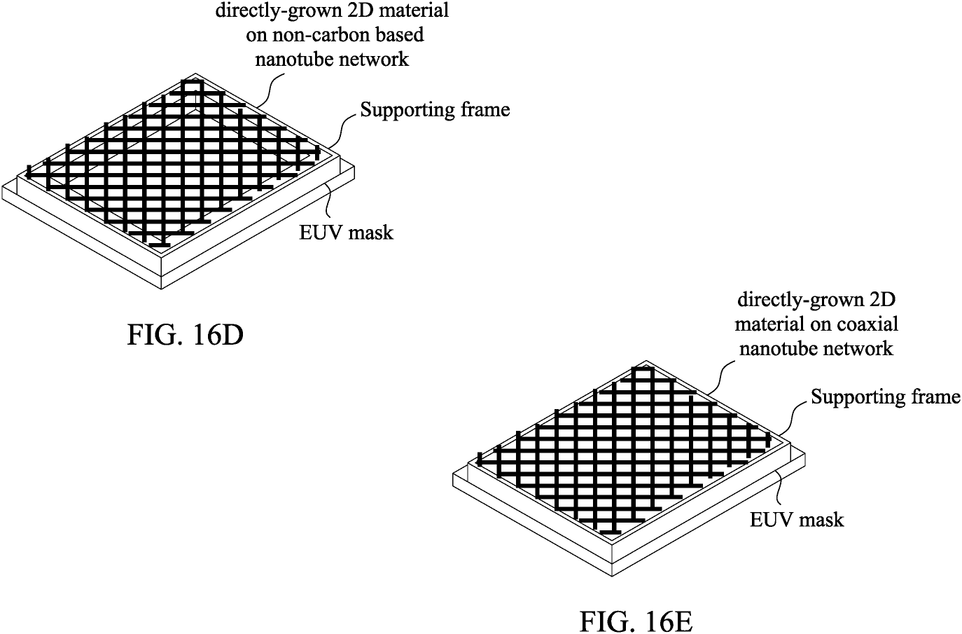

FIGS. 16A-16E show structures of pellicles in accordance with some embodiments of the present disclosure. Materials, configurations, methods, processes and/or dimensions as explained with respect to the foregoing embodiments are applicable to the following embodiments, and the detailed description thereof may be omitted.

In some embodiments, the main membrane of the pellicle is a single layer of a nanotube network as shown in FIG. 16A. In some embodiments, the nanotube network is formed by single wall nanotubes. In some embodiments, the single wall nanotubes are made of a non-carbon based material, such as BN or TMD. In some embodiments, two or more layers of single wall nanotube layers are stacked to form the main membrane as shown in FIG. 16B. In some embodiments, orientations of two adjacent nanotube layers are different from each other. In some embodiments, the main membrane is formed by multiwall nanotubes, as shown in FIG. 16C. In some embodiments, the multiwall nanotubes include an innermost nanotube and one or more outer nanotubes, one of which is made of a non-carbon based material, such as BN or TMD.

In some embodiments, the main membrane includes a nanotube layer having a mesh structure formed by single wall nanotubes, in which voids of the mesh structure are partially or fully filled by two-dimensional material layers as shown in FIG. 16D. In some embodiments, the single wall nanotubes are made of a non-carbon based material, such as BN or TMD. In other embodiments, the main membrane includes a nanotube layer having a mesh structure formed by multiwall nanotubes, in which voids of the mesh structure are partially or fully filled by two-dimensional material layers as shown in FIG. 16E.

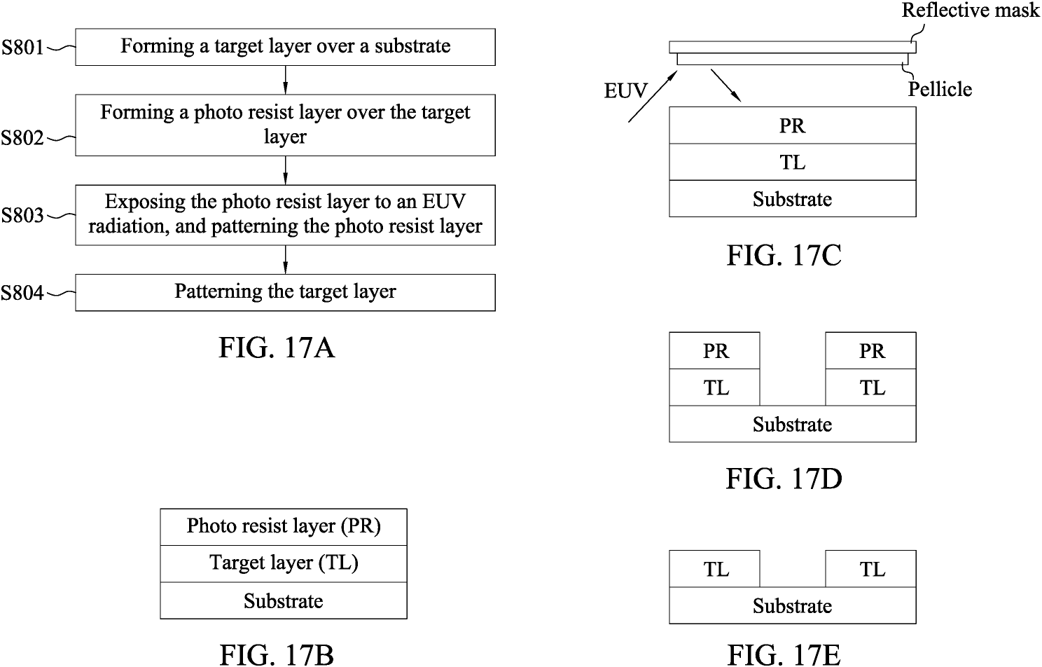

FIG. 17A shows a flowchart of a method of making a semiconductor device, and FIGS. 17B, 17C, 17D and 17E show a sequential manufacturing method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S801 of FIG. 17A, a target layer to be patterned is formed over the semiconductor substrate. In certain embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings. At S802, of FIG. 17A, a photo resist layer is formed over the target layer, as shown in FIG. 17B. The photo resist layer is sensitive to the radiation from the exposing source during a subsequent photolithography exposing process. In the present embodiment, the photo resist layer is sensitive to EUV light used in the photolithography exposing process. The photo resist layer may be formed over the target layer by spin-on coating or other suitable technique. The coated photo resist layer may be further baked to drive out solvent in the photo resist layer. At S803 of FIG. 17A, the photo resist layer is patterned using an EUV reflective mask with a pellicle as set forth above, as shown in FIG. 17C. The patterning of the photo resist layer includes performing a photolithography exposing process by an EUV exposing system using the EUV mask. During the exposing process, the integrated circuit (IC) design pattern defined on the EUV mask is imaged to the photo resist layer to form a latent pattern thereon. The patterning of the photo resist layer further includes developing the exposed photo resist layer to form a patterned photo resist layer having one or more openings. In one embodiment where the photo resist layer is a positive tone photo resist layer, the exposed portions of the photo resist layer are removed during the developing process. The patterning of the photo resist layer may further include other process steps, such as various baking steps at different stages. For example, a post-exposure-baking (PEB) process may be implemented after the photolithography exposing process and before the developing process.

At S804 of FIG. 17A, the target layer is patterned utilizing the patterned photo resist layer as an etching mask, as shown in FIG. 17D. In some embodiments, the patterning the target layer includes applying an etching process to the target layer using the patterned photo resist layer as an etch mask. The portions of the target layer exposed within the openings of the patterned photo resist layer are etched while the remaining portions are protected from etching. Further, the patterned photo resist layer may be removed by wet stripping or plasma ashing, as shown in FIG. 17E.

The pellicles according to embodiments of the present disclosure provide higher strength and thermal conductivity (dissipation) as well as higher EUV transmittance than conventional pellicles. In the foregoing embodiments, multiwall nanotubes are used as a main network membrane to increase the mechanical strength of the pellicle and obtain a high EUV transmittance. Further, a two-dimensional material layer is directly formed over the nanotube mesh network to partially or fully fills the voids in the mesh network to increase the mechanical strength of a pellicle, to improve thermal dissipation property of the pellicle, and to provide a high or perfect blocking property of killer particles.

It will be understood that not all advantages have been necessarily discussed herein, no particular advantage is required for all embodiments or examples, and other embodiments or examples may offer different advantages.

In accordance with one aspect of the present disclosure, a pellicle for an extreme ultraviolet (EUV) reflective mask includes a pellicle frame and a main membrane attached to the pellicle frame. The main membrane includes a plurality of nanotubes, each of which includes a single nanotube or a co-axial nanotube, and the single nanotube or an outermost nanotube of the co-axial nanotube is a non-carbon based nanotube. In one or more of the foregoing and following embodiments, the non-carbon based nanotube is one selected from the group consisting of a boron nitride nanotube and a transition metal dichalcogenide (TMD) nanotube, where TMD is represented by MX₂, where M is one or more of Mo, W, Pd, Pt, or Hf, and X is one or more of S, Se or Te. In one or more of the foregoing and following embodiments, the plurality of nanotubes include the co-axial nanotube having an inner tube and one or more outer tubes, and the inner tube is a carbon nanotube. In one or more of the foregoing and following embodiments, the plurality of nanotubes include the co-axial nanotube having an inner tube and one or more outer tubes made of a different material than the inner tube. In one or more of the foregoing and following embodiments, the plurality of nanotubes include the co-axial nanotube having an inner tube and one or more outer tubes, all of which are made of different materials from each other. In one or more of the foregoing and following embodiments, the plurality of nanotubes include the co-axial nanotube having an inner tube and one or more outer tubes, all of which are the non-carbon based nanotube. In one or more of the foregoing and following embodiments, the main membrane comprises a mesh formed by the plurality of nanotubes.

In accordance with another aspect of the present disclosure, a pellicle for an extreme ultraviolet (EUV) reflective mask includes a pellicle frame and a main membrane attached to the pellicle frame. The main membrane includes a plurality of nanotube layers, and nanotubes of a first layer of the plurality of nanotube layers are arranged along a first axis and nanotubes of a second layer of the plurality of nanotube layers adjacent to the first layer are arranged along a second axis crossing the first axis. In one or more of the foregoing and following embodiments, more than 90% of the nanotubes of the first layer have angles of ± 15 degrees with respect to the first axis, when each of the nanotubes of the first layer is subjected to linear approximation, and more than 90% of the nanotubes of the second layer have angles of ± 15 degrees with respect to the second axis, when each of the nanotubes of the second layer is subjected to linear approximation. In one or more of the foregoing and following embodiments, the first axis and the second axis form an angle of 30 degrees to 90 degrees. In one or more of the foregoing and following embodiments, a total number of layers of the plurality of nanotube layers is 2 to 8. In one or more of the foregoing and following embodiments, one layer of the plurality of nanotube layers comprises a plurality of single wall nanotubes covered by a non-carbon based material layer. In one or more of the foregoing and following embodiments, the non-carbon based material layer is made of one selected from the group consisting of boron nitride and transition metal dichalcogenide (TMD), where TMD is represented by MX₂, where M is one or more of Mo, W, Pd, Pt, or Hf, and X is one or more of S, Se or Te. In one or more of the foregoing and following embodiments, at least one of the single wall nanotubes touches another of the single wall nanotubes without interposing the non-carbon based material layer. In one or more of the foregoing and following embodiments, the non-carbon based material layer comprises a nanotube co-axially surrounding each of the plurality of single wall nanotubes. In one or more of the foregoing and following embodiments, each layer of the plurality of nanotube layers comprises a plurality of multiwall nanotubes. In one or more of the foregoing and following embodiments, each of the plurality of multiwall nanotubes comprises an inner tube and one or more outer tubes made of a non-carbon based material.

In accordance with another aspect of the present disclosure, a pellicle for an extreme ultraviolet (EUV) reflective mask includes a pellicle frame and a main membrane attached to the pellicle frame. The main membrane includes a mesh of a plurality of nanotubes and a two-dimensional material layer at least partially filling spaces of the mesh. In one or more of the foregoing and following embodiments, the two-dimensional material layer includes at least one selected from the group consisting of boron nitride (BN), MoS₂, MoSe₂, WS₂, and WSe₂. In one or more of the foregoing and following embodiments, at least one of the spaces is fully filled by the two-dimensional material layer, and at least one of the spaces is only partially filled by the two-dimensional material layer. In one or more of the foregoing and following embodiments, the plurality of nanotubes include single wall nanotubes. In one or more of the foregoing and following embodiments, the plurality of nanotubes include multiwall nanotubes. In one or more of the foregoing and following embodiments, the main membrane includes voids each having an area of 10 nm² to 1000 nm².

In accordance with another aspect of the present disclosure, in a method of manufacturing a pellicle for an extreme ultraviolet (EUV) reflective mask, a nanotube layer including a plurality of nanotubes is formed, and a two-dimensional material layer is formed over the nanotube layer. In one or more of the foregoing and following embodiments, the nanotube layer comprises a mesh of the plurality of nanotubes, and the two-dimensional material layer grows from intersections of the mesh as seeds. In one or more of the foregoing and following embodiments, the two-dimensional material layer is one selected from the group consisting of boron nitride and transition metal dichalcogenide (TMD), where TMD is represented by MX₂, where M is one or more of Mo, W, Pd, Pt, or Hf, and X is one or more of S, Se or Te. In one or more of the foregoing and following embodiments, a thickness of the two-dimensional material layer is in a range from 0.3 nm to 3 nm. In one or more of the foregoing and following embodiments, a number of layers of the two-dimensional material layer is 1 to 10. In one or more of the foregoing and following embodiments, the plurality of nanotubes are single wall nanotubes. In one or more of the foregoing and following embodiments, the single wall nanotubes are made of a non-carbon based material. In one or more of the foregoing and following embodiments, the non-carbon based material is one selected from the group consisting of boron nitride and transition metal dichalcogenide (TMD), where TMD is represented by MX₂, where M is one or more of Mo, W, Pd, Pt, or Hf, and X is one or more of S, Se or Te. In one or more of the foregoing and following embodiments, the plurality of nanotubes are multiwall nanotubes. In one or more of the foregoing and following embodiments, at least one tube of each of the multiwall nanotubes is made of one selected from the group consisting of boron nitride and transition metal dichalcogenide (TMD), where TMD is represented by MX₂, where M is one or more of Mo, W, Pd, Pt, or Hf, and X is one or more of S, Se or Te.

In accordance with another aspect of the present disclosure, in a method of manufacturing a pellicle for an extreme ultraviolet (EUV) reflective mask, a first nanotube layer including a plurality of nanotubes is formed, a second nanotube layer including a plurality of nanotubes is formed, and the first nanotube layer and the second nanotube layer are stacked over a pellicle frame. The plurality of nanotubes of the first nanotube layer are arranged along a first axis and the plurality of nanotubes of the second nanotube layer are arranged along a second axis, and the first nanotube layer and the second nanotube layer are stacked so that the first axis crosses the second axis. In one or more of the foregoing and following embodiments, more than 90% of the plurality of nanotubes of the first nanotube layer have angles of ± 15 degrees with respect to the first axis, when each of the plurality of nanotubes of the first nanotube layer is subjected to linear approximation, and more than 90% of the plurality of nanotubes of the second nanotube layer have angles of ± 15 degrees with respect to the second axis, when each of the plurality of nanotubes of the second nanotube layer is subjected to linear approximation. In one or more of the foregoing and following embodiments, the first axis and the second axis form an angle of 30 degrees to 90 degrees. In one or more of the foregoing and following embodiments, at least one of the first nanotube layer or the second nanotube layer comprises a plurality of single wall nanotubes made of a non-carbon based material. In one or more of the foregoing and following embodiments, the non-carbon based material is made of one selected from the group consisting of boron nitride and transition metal dichalcogenide (TMD), where TMD is represented by MX₂, where M is one or more of Mo, W, Pd, Pt, or Hf, and X is one or more of S, Se or Te. In one or more of the foregoing and following embodiments, at least one of the first nanotube layer or the second nanotube layer comprises a plurality of multiwall nanotubes. In one or more of the foregoing and following embodiments, each of the plurality of multiwall nanotubes comprises an inner tube and one or more outer tubes made of a non-carbon based material.

In accordance with another aspect of the present disclosure, in a method of manufacturing a pellicle for an extreme ultraviolet (EUV) reflective mask, a nanotube layer including a plurality of nanotubes is formed over a support substrate while rotating the support substrate, a pellicle frame is attached over the nanotube layer, and the nanotube layer is detached from the support substrate. In one or more of the foregoing and following embodiments, the plurality of nanotubes include a non-carbon based material. In one or more of the foregoing and following embodiments, the plurality of nanotubes form a mesh having voids each having an area of 10 nm² to 1000 nm².

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a pellicle for an extreme ultraviolet (EUV) reflective mask, comprising:
forming a nanotube layer including a plurality of nanotubes;
forming a two-dimensional material layer over the nanotube layer; and
attaching a pellicle frame to the nanotube layer with the two-dimensional material layer.

2. The method of claim 1, wherein:
the nanotube layer comprises a mesh of the plurality of nanotubes, and
the two-dimensional material layer grows from intersections of the mesh as seeds.

3. The method of claim 1, wherein the two-dimensional material layer is one selected from the group consisting of boron nitride and transition metal dichalcogenide (TMD), where TMD is represented by MX₂, where M is one or more of Mo, W, Pd, Pt, or Hf, and X is one or more of S, Se or Te.

4. The method of claim 3, wherein a thickness of the two-dimensional material layer is in a range from 0.3 nm to 3 nm.

5. The method of claim 4, wherein a number of layers of the two-dimensional material layer is 1 to 10.

6. The method of claim 1, wherein the plurality of nanotubes are single wall nanotubes.

7. The method of claim 6, wherein the single wall nanotubes are made of a non-carbon based material.

8. The method of claim 7, wherein the non-carbon based material is one selected from the group consisting of boron nitride and transition metal dichalcogenide (TMD), where TMD is represented by MX₂, where M is one or more of Mo, W, Pd, Pt, or Hf, and X is one or more of S, Se or Te.

9. The method of claim 1, wherein the plurality of nanotubes are multiwall nanotubes.

10. The method of claim 9, wherein at least one tube of each of the multiwall nanotubes is made of one selected from the group consisting of boron nitride and transition metal dichalcogenide (TMD), where TMD is represented by MX₂, where M is one or more of Mo, W, Pd, Pt, or Hf, and X is one or more of S, Se or Te.

11. A method of manufacturing a pellicle for an extreme ultraviolet (EUV) reflective mask, comprising:
forming a first nanotube layer including a plurality of nanotubes;
forming a second nanotube layer including a plurality of nanotubes; and
stacking the first nanotube layer and the second nanotube layer over a pellicle frame, wherein:
the plurality of nanotubes of the first nanotube layer are arranged along a first axis and the plurality of nanotubes of the second nanotube layer are arranged along a second axis, and
the first nanotube layer and the second nanotube layer are stacked so that the first axis crosses the second axis.

12. The method of claim 11, wherein:
more than 90% of the plurality of nanotubes of the first nanotube layer have angles of± 15 degrees with respect to the first axis, when each of the plurality of nanotubes of the first nanotube layer is subjected to linear approximation, and
more than 90% of the plurality of nanotubes of the second nanotube layer have angles of ± 15 degrees with respect to the second axis, when each of the plurality of nanotubes of the second nanotube layer is subjected to linear approximation.

13. The method of claim 12, wherein the first axis and the second axis form an angle of 30 degrees to 90 degrees.

14. The method of claim 12, wherein at least one of the first nanotube layer or the second nanotube layer comprises a plurality of single wall nanotubes made of a non-carbon based material.

15. The method of claim 14, wherein the non-carbon based material is made of one selected from the group consisting of boron nitride and transition metal dichalcogenide (TMD), where TMD is represented by MX₂, where M is one or more of Mo, W, Pd, Pt, or Hf, and X is one or more of S, Se or Te.

16. The method of claim 12, wherein at least one of the first nanotube layer or the second nanotube layer comprises a plurality of multiwall nanotubes.

17. The method of claim 16, wherein each of the plurality of multiwall nanotubes comprises an inner tube and one or more outer tubes made of a non-carbon based material.

18. A pellicle for an extreme ultraviolet (EUV) reflective mask, comprising:
a pellicle frame; and
a main membrane attached to the pellicle frame, wherein:
the main membrane includes a plurality of nanotubes, each of which includes a single nanotube or a co-axial nanotube, and
the single nanotube or an outermost nanotube of the co-axial nanotube is a non-carbon based nanotube.

19. The pellicle of claim 18 wherein the non-carbon based nanotube is one selected from the group consisting of a boron nitride nanotube and a transition metal dichalcogenide (TMD) nanotube, where TMD is represented by MX₂, where M is one or more of Mo, W, Pd, Pt, or Hf, and X is one or more of S, Se or Te.

20. The pellicle of claim 19, wherein the plurality of nanotubes include the co-axial nanotube having an inner tube and one or more outer tubes, and the inner tube is a carbon nanotube.
